(19) United States
(12) Patent Application Publication
(10) Pub. No.: US 2008/0164888 A1
(43) Pub. Date: Jul. 10, 2008

(54) Electrostatic capacity sensor

(75) Inventors: Toshihisa Suzuki, Hamamatsu-shi (JP); Akiyoshi Sato, Hamamatsu-shi (JP); Masamitsu Hirano, Hamamatsu-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 12/002,927

(22) Filed: Dec. 19, 2007

(30) Foreign Application Priority Data
Dec. 22, 2006 (JP) 2006-345400

(51) Int. Cl. G01R 27/26

(52) U.S. Cl. 324/686

(57) ABSTRACT

An electrostatic capacity sensor includes a sensor die including a bias electrode and a signal electrode, which are positioned opposite to each other with a very small distance therebetween, and a shield member including a potential stabilizing conductive film whose external shape encompasses the vertically projected area of the signal electrode. The sensor die joins the joint surface of the shield member. The signal electrode is positioned between the bias electrode and the potential stabilizing conductive film. A noise shield adapted to the signal electrode is formed using the bias electrode and the potential stabilizing conductive film; hence, it is possible to improve the noise resistance of the signal electrode and to increase the S/N ratio in sensitivity.

### BACKGROUND OF THE INVENTION

1. Field of the Invention

The present invention relates to electrostatic capacity sensors such as MEMS (Micro-Electro-Mechanical System) condenser microphones.

This application claims priority on Japanese Patent Application No. 2006-345400, the content of which is incorporated herein by reference.

2. Description of the Related Art

As conventionally-known electrostatic capacity sensors, MEMS sensors such as condenser microphones encapsulated in MEMS packages have been disclosed in various documents such as Japanese Patent Application Publication No. 2004-537182, U.S. Patent Application Publication No. US 2004/0046245 A1, and U.S. Patent Application Publication No. US 2005/0018864 A1. Each of the electrostatic capacity sensors serving as condenser microphones has opposite electrodes having high impedances. For this reason, a cover of a package (i.e., a package cover) of the electrostatic capacity sensor is composed of a conductor being grounded so as to serve as a noise shield.

The aforementioned documents teach that the package cover of the condenser microphone has an opening allowing sound waves to enter the inside of the package. This unexpectedly allows noise due to electromagnetic induction of electric lighting to be introduced into the output signal of the condenser microphone, thus reducing the S/N ratio.

### SUMMARY OF THE INVENTION

It is an object of the present invention to provide an electrostatic capacity sensor having a high S/N ratio.

In a first aspect of the present invention, an electrostatic capacity sensor includes a sensor die including a bias electrode and a signal electrode, which are positioned opposite to each other, and a shield member having a joint surface joining the sensor die, wherein the shield member includes a potential stabilizing conductive film whose external shape encompasses a vertically projected area of the signal electrode in plan view, and wherein the signal electrode is positioned between the bias electrode and the potential stabilizing conductive film.

In the above, the high-impedance signal electrode is sandwiched between the potential stabilizing conductive film (whose potential is stabilized) and the bias electrode (applied with a stabilized bias), both of which are stabilized in potential, wherein the signal electrode overlaps the bias electrode and the potential stabilizing conductive film in plan view. The distance between the bias electrode and the signal electrode is very small and ranges from several microns to several sub-microns, for example. Herein, a noise shield for the signal electrode is formed using the bias electrode, which is very proximate to the signal electrode, and the potential stabilizing conductive film of the shield member joining the sensor die. Compared with a noise shield formed using a package cover, which is separated from the sensor die, it is possible to improve the noise resistance with respect to the signal electrode. That is, it is possible for the electrostatic capacity sensor to realize a high S/N ratio without using the package cover (serving as the noise shield) and another external noise shield.

Bias or potential being stabilized indicates that an electrode or a film is connected to a stabilized power circuit, grounded, or connected to a conductor having a large capacity. An element for stabilizing potential is not necessarily limited as to whether it is active or passive. The positional relationship between the element for stabilizing potential and the electrostatic capacity sensor is not necessarily limited as to whether the element is positioned relative to or inside of the electrostatic capacity sensor. The term “ground” is not necessarily limited to “earth”; hence, it has a broad meaning in technology including any type of conductor establishing a reference potential compared with a signal potential. The term “vertically projected area” indicates a region corresponding to a shadow that appears when an object is vertically projected with respect to a prescribed projection surface. For example, when the external shape of the potential stabilizing conductive film, which is stabilized in potential, embraces the vertically projected area of the signal electrode, the interlayer boundary of the potential stabilizing conductive film serves as the projection surface so that the signal electrode is vertically projected with respect to the interlayer boundary so as to produce a virtual shadow region, which corresponds to the vertically projected area of the signal electrode.

In the electrostatic capacity sensor, the sensor die includes a plate having a plurality of sound holes and forming the signal electrode, a diaphragm forming the bias electrode, which vibrates relative to the plate due to sound waves, and a die substrate having a through-hole for exposing the diaphragm and supporting the plate and the diaphragm, wherein the sensor die joins the joint surface of the shield member via an acoustic passage communicating with the sound holes. This electrostatic capacity sensor forms an MEMS condenser microphone, wherein sound waves are transmitted through the acoustic passage (corresponding to the gap between the sensor die and the joint surface of the multilayered wiring substrate) and are then transmitted through the sound holes of the plate so as to reach the diaphragm, which thus vibrates due to sound waves.

The electrostatic capacity sensor further includes an impedance converter that is connected to the signal electrode so as to reduce the output impedance, and a drive die joining the joint surface of the shield member. Herein, the shield member corresponds to a multilayered wiring substrate including a potential stabilizing conductive film, a second potential stabilizing conductive film whose potential is stabilized, and a signal line that is positioned between the potential stabilizing conductive film and the second potential stabilizing conductive film and that partially overlaps the potential stabilizing conductive film and the second potential stabilizing conductive film so as to connect the signal electrode and the impedance converter together.

In this connection, the output impedance of the electrostatic capacity sensor is reduced by means of the impedance converter of the drive die. In addition, the high-impedance signal electrode is sandwiched between the bias electrode and the potential stabilizing conductive film of the multilayered wiring substrate. Furthermore, the signal line for connecting the signal electrode and the impedance converter together is sandwiched between the potential stabilizing conductive film and the second potential stabilizing conductive film and partially overlaps with them in plan view. That is, it is possible to improve the noise resistance with respect to the high-impedance signal line by means of two conductive films, which are positioned proximate to the signal line and are stabilized in potential. Thus, it is possible to further increase the S/N ratio of the electrostatic capacity sensor.

The electrostatic capacity sensor further includes a package cover that is combined with the multilayered wiring substrate so as to define an internal space for embracing the sensor die and the drive die. This makes it possible for the electrostatic capacity sensor to protect the internal circuitry from dust and light in external environments. This makes the electrostatic capacity sensor easy-to-handle.

In the electrostatic capacity sensor, the sensor die includes a plate having a plurality of sound holes and forming the signal electrode, a diaphragm forming the bias electrode that vibrates relative to the plate due to sound waves, and a die substrate having a through-hole for exposing the diaphragm and supporting the plate and the diaphragm, wherein the sensor die joins the joint surface of the shield member via an acoustic passage for communicating the sound holes with the internal space, and wherein the package cover has an opening for communicating the internal space with an external space. The electrostatic capacity sensor further includes a gasket that joins the surface of the sensor die and that has an internal cavity, which is isolated from the internal space and communicates with the through-hole of the die substrate.

The aforementioned electrostatic capacity sensor forms an MEMS condenser microphone, wherein sound waves are transmitted through the opening of the package cover and through the acoustic passage (corresponding to the gap between the sensor die and the joint surface of the multilayered wiring substrate) and are then transmitted through the sound holes of the plate so as to reach the diaphragm, which thus vibrates due to sound waves. Herein, a back cavity is positioned in connection with the backside of the diaphragm and includes the through-hole of the die substrate of the sensor die and the internal cavity of the gasket joining the sensor die. The back cavity is isolated from the space allowing sound waves to reach the diaphragm by means of the die substrate of the sensor die and the gasket. As the volume of the back cavity increases, the cutoff frequency decreases so as to increase the sensitivity in low bands. In conventionally-known condenser microphones, the die substrate of the sensor die (composed of a silicon wafer) joins the multilayered wiring substrate, and the through-hole of the die substrate is closed by the multilayered wiring substrate so as to form the back cavity. In the condenser microphone of the present invention compared with the conventionally-known condenser microphones, the back cavity is formed between the package cover, which is distanced from the sensor die, and the diaphragm; hence, it is possible to increase the volume of the back cavity. That is, the condenser microphone of the present invention can reduce the cutoff frequency and can increase the sensitivity in low bands in comparison with the conventionally-known condenser microphones.

In the electrostatic capacity sensor, the joint surface of the shield member has a recess forming the interior wall of the acoustic passage. Due to the provision of the recess and projection with respect to the joint surface of the multilayered wiring substrate, it is possible to increase the degree of freedom with respect to the acoustic impedance and resonance frequency in the acoustic passage allowing sound waves to be transmitted to the diaphragm. In addition, the recess can be easily formed by way of lamination of ceramic sheets having different external shapes on the joint surface of the multilayered wiring substrate.

In the electrostatic capacity sensor, the sensor die joins the multilayered wiring substrate in a flip-chip connection manner. In this connection, it is possible to reduce the foot print of the package. In addition, the gap between solder balls or bumps may form the acoustic passage for communicating the sound holes of the plate and the internal space of the package.

In the electrostatic capacity sensor, the multilayered wiring substrate includes a bias line for connecting both the bias electrode and the die substrate to a stabilized power circuit, wherein both the potential stabilizing conductive film and the second potential stabilizing conductive film are grounded. In this connection, the noise shield effect is applied entirely to the vertically projected area of the sensor die in the multilayered wiring substrate; hence, although the signal line does not partially overlap the bias electrode, in other words, although the signal line passes through the vertically projected area of the sensor die but externally of the vertically projected area of the bias electrode, it is possible to improve the noise resistance in the electrostatic capacity sensor without arranging an additional noise shield.

In the electrostatic capacity sensor, the potential stabilizing conductive film connects both the bias electrode and the die substrate to a stabilized power circuit. In this connection, the noise shield effect is applied entirely to the vertically projected area of the sensor die in the multilayered wiring substrate; hence, although the signal line does not partially overlap with the bias electrode, in other words, although the signal line passes through the vertically projected area of the sensor die but externally of the vertically projected area of the bias electrode, it is possible to improve the noise resistance with respect to the electrostatic capacity sensor without arranging an additional noise shield. In addition, this eliminates the necessity of additionally introducing a “grounded” conductive film (that serves as a noise shield only) to the backside of the signal line in view of the sensor die; hence, it is possible to simplify the structure of the multilayered wiring substrate.

In the electrostatic capacity sensor, the second potential stabilizing conductive film is connected to the potential stabilizing conductive film. In this connection, the signal line is sandwiched between two conductive films, both of which are stabilized in potential, in the multilayered wiring substrate.

In a second aspect of the present invention, an electronic device is designed to include the aforementioned electrostatic capacity sensor whose multilayered wiring substrate joins an external wiring substrate. Herein, the high-impedance signal electrode and the high-impedance signal line are sandwiched between the conductive films, which are stabilized in potential, in the electrostatic capacity sensor; hence, it is unnecessary to additionally provide a noise shield (for use in the electrostatic capacity sensor) with respect to the external wiring substrate. That is, it is possible for the electronic device to reduce the cost for the noise shield and to increase the S/N ratio with respect to the electrostatic capacity sensor.

### BRIEF DESCRIPTION OF THE DRAWINGS

These and other objects, aspects, and embodiments of the present invention will be described in more detail with reference to the following drawings, in which:

FIG. 1A is a longitudinal sectional view showing the constitution of a condenser microphone in accordance with a preferred embodiment of the present invention;

FIG. 1B is a plan view of the condenser microphone shown in FIG. 1A;

FIG. 2 is a simple sectional view showing the basic constitution of an electrostatic capacity sensor composed of a sensor die and a shield member in accordance with the present invention;

FIG. 3 is a simple sectional view showing the constitution of the electrostatic capacity sensor in which the shield member is formed using a multilayered wiring substrate;

FIG. 4 is a simple sectional view showing the constitution of the electrostatic capacity sensor that serves as a MEMS condenser microphone;

FIG. 5 is a longitudinal sectional view showing the constitution of a condenser microphone according to a first variation of the embodiment;

FIG. 6 is a longitudinal sectional view showing the constitution of a condenser microphone according to a second variation of the embodiment; and

FIG. 7 is a longitudinal sectional view showing the constitution of a condenser microphone according to a third variation of the embodiment.

### DESCRIPTION OF THE PREFERRED EMBODIMENT

The present invention will be described in further detail by way of examples with reference to the accompanying drawings.

### 1. Basic Constitution and Operating Principle

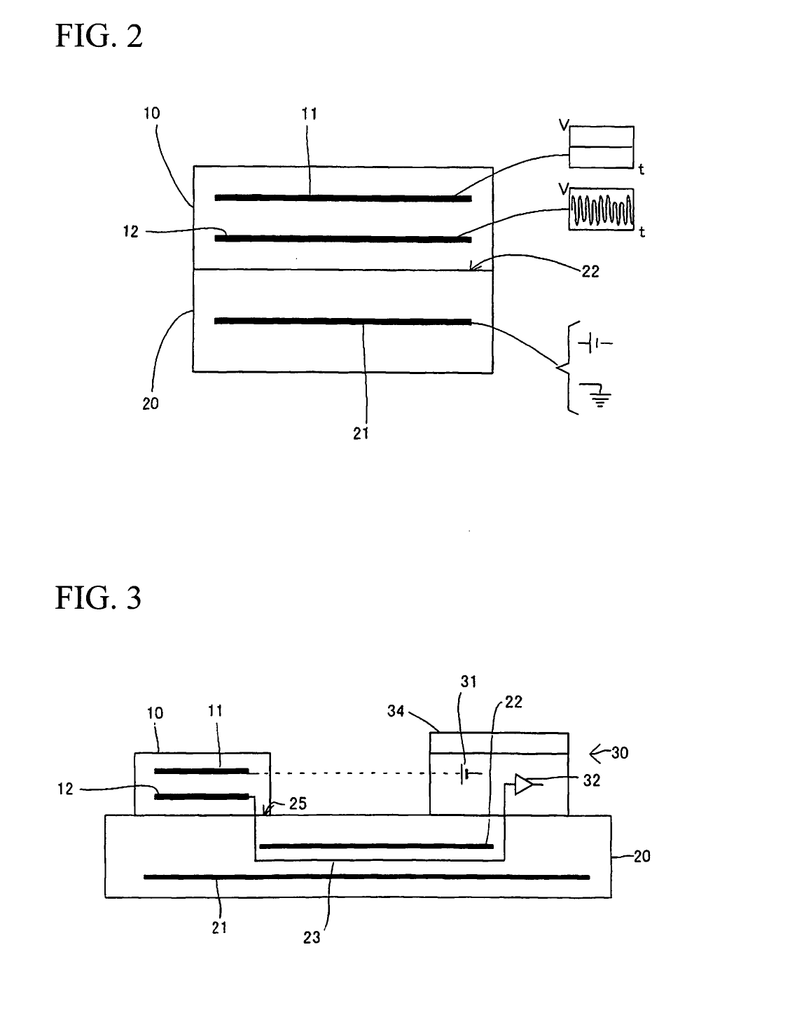

Before specifically describing a condenser microphone according to a preferred embodiment of the present invention, the basic constitution and the basic operating principle will be described in detail with reference to FIGS. 2, 3, and 4.

FIG. 2 is a simple sectional view diagrammatically showing the basic constitution of an electrostatic capacity sensor of the present invention. As shown in FIG. 2, the electrostatic capacity sensor of the present invention is constituted of at least a sensor die 10 and a shield member 20.

The sensor die 10 is an MEMS die including a bias electrode 11 (which serves as one of opposite electrodes and which is applied with a bias voltage) and a signal electrode 12 (which serves as the other of opposite electrodes). It is possible to form constituent elements of the sensor die 10 such as the bias electrode 11 and the signal electrode 12 by way of the formation of thin films or membranes in accordance with various formation technologies. That is, it is possible to adopt photolithography technology, fine processing technology, and thin-film forming technology, specifically, chemical vapor deposition (CVD), photoelectric vapor deposition (PVD), and nano-imprint technology in the manufacturing of the sensor die 10. In order to realize conversion for converting physical values such as pressure, acceleration, and sound waves into electric signals, the bias electrode 11 and the signal electrode 12 being supported are mutually distanced from each other so as to make the distance therebetween variable. Actually, the bias electrode 11 and the signal electrode 12 can be designed such that one of them is deformable or movable or such that both of them are deformable or movable. Herein, a condenser (or a capacitor) composed of the bias electrode 11 and the signal electrode 12 is incorporated into the circuitry in which the potential of the signal electrode 12 varies due to variations of electrostatic capacity.

Since the signal electrode 12 has a high impedance, it is necessary to adopt the following noise shield measure to the signal electrode 12 inside of the electrostatic capacity sensor. That is, conductive films for stabilizing potentials are arranged on both of the surface and backside of the signal electrode 12 composed of a thin film, wherein they partially overlap the signal electrode 12 in proximity to the signal electrode 12. Specifically, one of the conductive films corresponds to the bias electrode 11, while the other corresponds to a potential stabilizing conductive film 21 adapted to the shield member 20. The external shape of the bias electrode 11 completely or substantially matches the external shape of the signal electrode 12, that is, the bias electrode 11 encompasses the vertically projected area of the signal electrode 12. Since both the bias electrode 11 and the signal electrode 12 are arranged on the same die, the distance therebetween is very small, and it may range from one micron (or 1 μm) to several sub-microns, for example. The external shape of the potential stabilizing conductive film 21 encompasses the vertically projected area of the signal electrode 12. Since the shield member 20 joins the sensor die 10, the distance between the potential stabilizing conductive film 21 of the shield member 20 and the signal electrode 12 is very small, and it may be several hundreds of microns. As the distance between the shield member 20 and the signal electrode 12 being affected by noise becomes small, it is possible to realize a small-size noise shield having a high shield effect. This is the reason why the noise shield is completely embedded inside the electrostatic capacity sensor so that the signal electrode 12 is arranged close to a prescribed part joining the sensor die 10 rather than the bias electrode 11.

The prescribed part joining the sensor die 10 is used to form the shield member 20 and can be a wiring substrate forming the bottom of a package or another die stacked with the sensor die 10, for example. The potential stabilizing conductive film 21 is grounded so as to stabilize the potential. Alternatively, the potential stabilizing conductive film 21 serves as a bias-voltage applied line so as to stabilize the potential.

FIG. 3 shows a variation of the electrostatic capacity sensor, in which the shield member 20 is formed using a multilayered wiring substrate. The electrostatic capacity sensor of FIG. 3 is constituted of a drive die 30 in addition to the sensor die 10 and the multilayered wiring substrate 20. Both the sensor die 10 and the drive die 30 join the multilayered wiring substrate 20.

The drive die (or an LSI chip) 30 is constituted of a stabilized power circuit 31, which applies a stabilized voltage to the bias electrode 11, an impedance converter 32, which reduces the output impedance of the electrostatic capacity sensor, and a die substrate 34 being grounded. Since the impedance converter 32 is arranged inside of the electrostatic capacity sensor, it is possible to completely embed a noise shield measure inside the electrostatic capacity sensor.

The surface of the multilayered wiring substrate 20 forms a joint surface 25 joining the sensor die 10 and the drive die 30. The backside of the multilayered wiring substrate 20, which is opposite to the joint surface 25, joins an external wiring substrate (not shown) for mounting other electronic devices together with the electrostatic capacity sensor. The multilayered wiring substrate 20 includes a signal line 23 for connecting the signal electrode 12 and the impedance converter 32. Since the signal line 23 connected to the signal electrode 12 has a high impedance, it is possible to adopt the following noise shield measure. That is, two conductive films are arranged above and below the signal line 23 via an insulating layer whose thickness ranges from 10 μm to 100 μm inside of the multilayered wiring substrate 20, wherein they partially overlap the signal line 23 so as to stabilize the potential. Herein, a noise shield is formed using the two conductive films. Specifically, one of the two conductive films corresponds to the “first” potential stabilizing conductive film 21 whose external shape encompasses the vertically projected area of the signal electrode 12, the vertically projected area of the signal line 23, and the vertically projected area of the drive die 30, while the other is a second potential stabilizing conductive film 22 whose external shape encompasses the vertically projected area of the signal line 23. Herein, one or both of the two conductive films are grounded so as to stabilize the potential. Alternatively, one or both of the two conductive films serve as bias-voltage applied lines so as to stabilize the potential. A floating capacity is formed by way of the signal line 23 and the two conductive films. However, since the thickness of the insulating layer included in the multilayered wiring substrate 20 is sufficiently large, it is possible to substantially neglect the floating capacity.

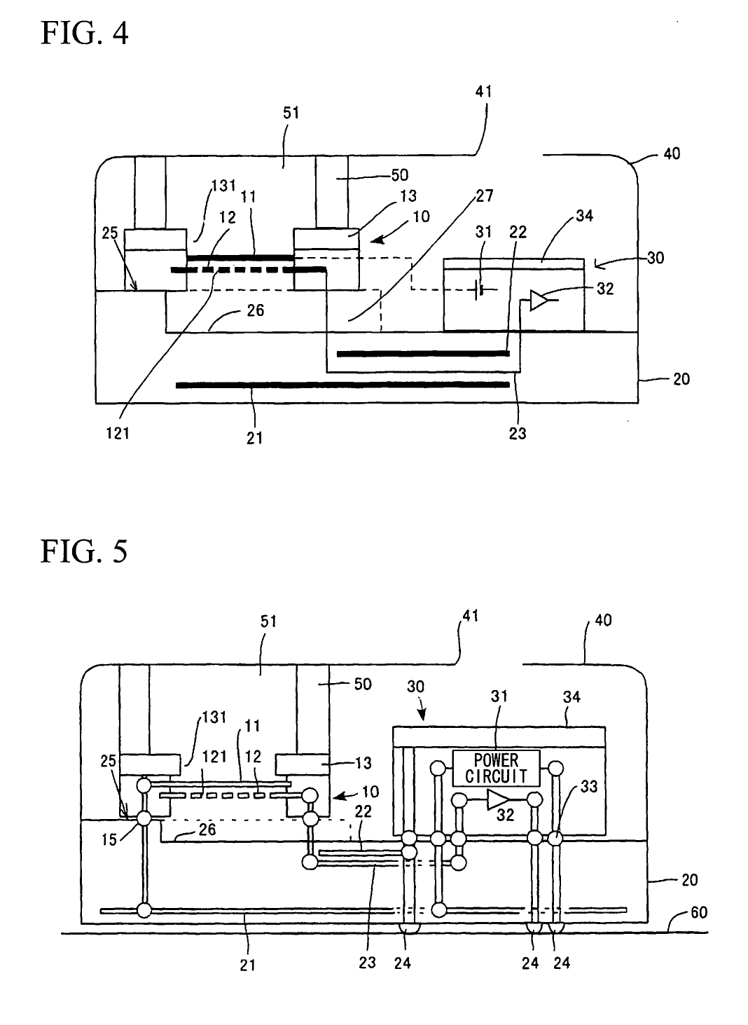

FIG. 4 shows another variation of the electrostatic capacity sensor that serves as a condenser microphone. Specifically, the condenser microphone of FIG. 4 is an MEMS condenser microphone constituted of the multilayered wiring substrate 20 and a package cover 40.

The package cover 40 has a box-like shape joining the multilayered wiring substrate 20. An opening 41 is formed at a prescribed position of the package cover 40 so as to introduce sound waves into the internal space of the package. The package cover 40 does not necessarily serve as a noise shield; hence, it is composed of an insulating material such as resin, ceramics, and glass. Since the package cover 40 is not necessarily grounded, it is possible to realize a relatively high degree of freedom in designing the opening 41 in terms of its position, size, and shape.

The sensor die 10 is constituted of a diaphragm 11 forming the bias electrode, a plate 12 forming the signal electrode, and a die substrate 13 applied with a bias voltage. Both the diaphragm 11 and the plate 12 are formed using thin films laminated on the die substrate 13, wherein each of them can be formed using a single conductive film or multiple conductive films; alternatively, each of them can be formed using a multilayered film composed of a conductive film and an insulating film. An insulating film (not shown) is further formed between the thin film of the diaphragm 11 and the thin film of the plate 12 so as to form a gap between the diaphragm 11 and the plate 12 and so as to insulate the bias electrode from the signal electrode.

When the signal electrode is composed of the plate 12 as shown in FIG. 4, it is possible to realize a noise shield by means of the bias electrode and the potential stabilizing conductive film 21. Herein, it is necessary to establish the positional relationship between the diaphragm 11, the plate 12, and the multilayered wiring substrate 20 in such a way that the plate 12 forming the signal electrode is sandwiched between the diaphragm 11 forming the bias electrode and the potential stabilizing conductive film 21 of the multilayered wiring substrate 20.

It is possible to change the positional relationship between the diaphragm 11, the plate 12, and the multilayered wiring substrate 20 in such a way that the diaphragm 11 forms the signal electrode while the plate 12 forms the bias electrode. However, FIG. 4 shows a simple constitution of the condenser microphone in which the diaphragm 11 forms the bias electrode while the plate 12 forms the signal electrode so as to improve a noise shield effect.

One of two spaces partitioned by the diaphragm 11 can be used to allow sound waves to reach the diaphragm 11; however, the space close to the multilayered wiring substrate 20 (i.e., the lower space of the diaphragm 11 in FIG. 4) allowing sound waves to reach the diaphragm 11 is advantageous since the cutoff frequency can be reduced so as to increase the sensitivity in low bands because of the following reasons.

In FIG. 4, the sensor die 10 joins the multilayered wiring substrate 20, so that a gap remains between the package cover 40 and the sensor die 10. Compared with the space positioned below the sensor die 10 in proximity to the multilayered wiring substrate 20, the space positioned above the sensor die 10 in proximity to the package cover 40 is large. In other words, it is possible to increase the volume of a back cavity, which is formed using the space positioned above the sensor die 10 in proximity to the package cover 40, to be larger than the volume of a back cavity, which is formed using the space positioned below the sensor die 10 in proximity to the multilayered wiring substrate 20. That is, when the back cavity is formed using the space positioned above the sensor die 10 in proximity to the package cover 40, sound waves reach the diaphragm 11 by way of the space positioned below the sensor die 10 in proximity to the multilayered wiring substrate 10; hence, it is possible to decrease the cutoff frequency and to increase the sensitivity in low bands.

In order to transmit sound waves to reach the diaphragm 11 by way of the space positioned below the sensor die 10 in proximity to the multilayered wiring substrate 20, it is necessary to form a through-hole running through the multilayered wiring substrate, which allows sound waves to be introduced into the internal space of the package, for example. However, this structure is disadvantageous in that noise may be picked up via the through-hole of the multilayered wiring substrate 20.

In order to transmit sound waves to reach the diaphragm 11 by way of the space positioned below the sensor die 10 in proximity to the multilayered wiring substrate 10 without forming a through-hole in the multilayered wiring substrate 20, it is necessary to form a gap forming an acoustic passage between the joint surface 25 of the multilayered wiring substrate 20 and the sensor die 10. In FIG. 4, a recess 26 is formed in the joint surface 25 of the multilayered wiring substrate 20, which joins the sensor die 10, so as to form an acoustic passage 27. Herein, the interior wall of the recess 26 forms the wall of the acoustic passage 27. This makes it possible to freely design the acoustic impedance and resonance frequency of the acoustic passage 27. This also makes it possible to connect the sensor die 10 and the multilayered wiring substrate 20 together in an appropriate manner allowing inspection and repair to be easily performed with respect to wire bonding and the like. When the sensor die 10 joins the multilayered wiring substrate 20 via a flip-chip connection, a gap may remain between projected electrodes such as bumps and solder balls. Unless such a gap is positively closed, the gap between the sensor die 10 and the multilayered wiring substrate 20 allows sound waves to reach the diaphragm 11; hence, the recess 26 is not always necessary.

A gasket 50 isolates the back cavity from the space allowing sound waves to be transmitted to the diaphragm 11. The gasket 50 is formed using a resin composed of polyimide, for example, wherein the gasket 50 has a prescribed external shape enclosing a hollow inside. If a packaging step and a mounting step for mounting the condenser microphone on the external wiring substrate are each performed at a relatively low heat treatment temperature, it is possible to form the gasket 50 by use of rubber and the like. The internal cavity of the gasket 50 communicates with a through-hole 131 formed in the die substrate 13, whereby the internal cavity of the gasket 50 and the through-hole 131 are combined together to form the back cavity. Incidentally, the diaphragm 11 is exposed in the through-hole 131.

One terminal of the gasket 50 joins the surface of the sensor die 10, while the other terminal joins the interior wall of the package cover 40. Therefore, the hollow cavity of the gasket 50 is isolated from the external space of the gasket 50. The gasket 50 can be closely attached to the sensor die 10 without a gap, or the gasket 50 can be closely attached to the package cover 40 without a gap. Alternatively, the gasket 50 can be attached to the sensor die 10 with a small gap therebetween, thus increasing the acoustic impedance in the audio frequency range to be sufficiently high, or the gasket 50 can be attached to the package cover 40 with a small gap therebetween, thus increasing the acoustic impedance in the audio frequency range to be sufficiently high. Such a gap may establish a balance between the internal pressure of the gasket 50 and the external atmospheric pressure. The gasket 50 can be redesigned in another external shape having a bottom, such as a cylindrical shape having a closed bottom and an opening that is closed by the sensor die 10, thus isolating the internal cavity of the gasket 50 from the external space.

Since the plate 12 is positioned in the space allowing the diaphragm 11 to receive sound waves, a plurality of sound holes 121 allowing sound waves to be transmitted therethrough are formed are formed in the plate 12. Therefore, sound waves input by the opening 41 of the package cover 40 are transmitted through the acoustic passage 27 between the multilayered wiring substrate 20 and the sensor die 10, and then sound waves are transmitted through the sound holes 121 of the plate 12 to reach the diaphragm 11. Since the plate 12 having the sound holes 121 has a relatively high rigidity that is higher than the rigidity of the diaphragm 11, vibration of the plate 12 due to sound waves is very small and negligible. For this reason, when sound waves reach the diaphragm 11, the diaphragm 11 vibrates relative to the plate 12 so as to cause variations of electrostatic capacity of the sensor die 10, thus causing variations of potential of the signal electrode corresponding to the plate 12.

### 2. Preferred Embodiment

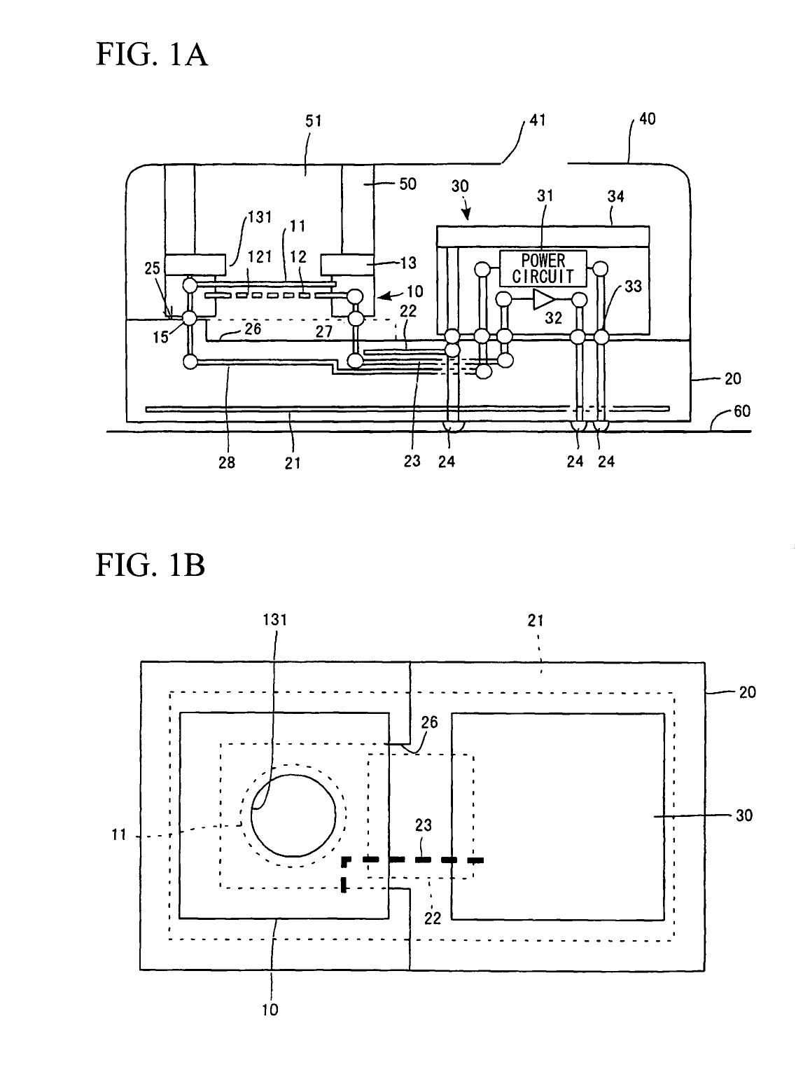

Next, an electrostatic capacity sensor realized by a condenser microphone will be described in detail in accordance with the preferred embodiment of the present invention with reference to FIGS. 1A and 1B. FIG. B is a plan view showing the state in which the package cover 40 and the gasket 50 are removed from the condenser microphone shown in FIG. 1A.

The sensor die 10 is an MEMS chip that is formed by dicing a wafer laminated with thin films.

Both of the diaphragm 11 and the plate 12 are composed of silicon thin films doped with impurities such as phosphorus. An insulating film (not shown) such as a silicon dioxide film is arranged between the peripheries of two silicon thin films forming the diaphragm 11 and the plate 12. The plate 12 is supported by the insulating film so as to form a gap with the diaphragm 11. The distance between the diaphragm 11 and the plate 12 ranges from 1 μm to 4 μm, for example. The width (or diameter) of the diaphragm 11 and the width (or diameter) of the plate 12 are each set to 1 mm, for example. No special limitation is applied to the external shape of the diaphragm 11 and the external shape of the plate 12. For example, both the diaphragm 11 and the plate 12 are formed in a concentric circular shape whose external circumference is entirely fixed. The diaphragm 11 and the plate 12 can overlap each other in plan view. Alternatively, they can partially overlap each other.

The die substrate 13 of the sensor die 10 is composed of a semiconductor including impurities such as silicon. An insulating film (not shown) such as a silicon dioxide film is arranged between the peripheral portion of the silicon thin film forming the diaphragm 11 and the die substrate 13. The diaphragm 11 is supported by the insulating film. The silicon thin film forming the diaphragm 11 (that serves as the bias electrode) is electrically connected to the die substrate 13 by way of a via or a joint. This makes it possible to apply a stable bias voltage to the die substrate 13, which thus functions as a noise shield. Therefore, the vertically projected area of the sensor die 10 is entirely shielded from noise by means of the diaphragm 11 that entirely overlap with the die substrate 13 and the through-hole 131 (formed in the die substrate 13) in plan view. In particular, the plate 12 serving as the signal electrode is shielded from noise by means of the diaphragm 11 (which is distanced from the plate 12 with 1 μm or so therebetween); hence, the plate 12 having a relatively high impedance is improved in noise resistance.

The drive die (or an LSI chip) 30 is formed in a structure in which a silicon-doped conductive thin film or an insulating film composed of silicon dioxide is laminated with the die substrate 13 doped with impurities such as silicon. The stabilized power circuit 31 (such as a charge pump) and the impedance converter 32 (such as an operational amplifier) are formed in the drive die 30. The stabilized power circuit 31 is connected to a solder ball 24 (serving as a power terminal) through a via. The output terminal of the impedance converter 32 is connected to a solder ball 24 (serving as a signal terminal) through a via. All circuit elements of the drive die 30 are connected to a solder ball 24 (serving as a ground terminal) through a via, so that they are shielded from noise.

The multilayered wiring substrate 20 is formed using three conductive films which are laminated together via a ceramic sheet and are subjected to burning. The sensor die 10 and the drive die 30 join the joint surface 25 of the multilayered wiring substrate 20 in a flip-chip connection manner by use of projection electrodes 15 and 33, which are composed of solder balls and bumps. The recess 26 of the joint surface 25 forming the wall of the acoustic passage 27 is formed by laminating a plurality of U-shaped ceramic sheets on a rectangular-shaped ceramic sheet as shown in FIG. 1B. A plurality of solder balls 24 for connecting wiring of the multilayered wiring substrate 20 and wiring of an external wiring substrate 60 are arranged on the backside of the multilayered wiring substrate 20, which corresponds to the bottom of a package.

The potential stabilizing conductive film 21 corresponds to the outermost conductive film of the three conductive films forming the multilayered wiring substrate 20 in the package, so that the external shape thereof encompasses the vertically projected area of all circuit elements (except for some vias) within the package. The potential stabilizing conductive film 21 is connected to a solder ball 24 (serving as a ground terminal, which is arranged in the bottom of the package) through a via. That is, the potential stabilizing conductive film 221 is grounded so as to stabilize the potential. Thus, the potential stabilizing conductive film 21 serves as a noise shield with respect to all circuit elements of the package. In particular, the plate 12 serving as the signal electrode is slightly distanced from the potential stabilizing conductive film 21 with several hundreds of microns; hence, it is possible to improve the noise resistance with respect to the plate 12 having a relatively high impedance.

The second potential stabilizing conductive film 22 corresponds to the innermost conductive film of the three conductive films forming the multilayered wiring substrate 20, wherein the external shape thereof completely covers the signal line 23, which partially ranges outside the vertically projected area of the sensor die 10 and the vertical projected area of the drive die 30. The second potential stabilizing conductive film 22 is connected to the first potential stabilizing conductive film 21 and the solder ball 24 serving as the ground terminal by way of a via. That is, the second potential stabilizing conductive film 22 is grounded so as to stabilize the potential.

The signal line 23, which connects the plate 12 serving as the signal electrode and the impedance converter 32 together, corresponds to the intermediate conductive film of the three conductive films forming the multilayered wiring substrate 20, wherein it is sandwiched between the first potential stabilizing conductive film 21 and the second potential stabilizing conductive film 22. In the package, a prescribed portion of the potential stabilizing conductive film 21, which is positioned externally from the signal line 23, functions as a noise shield, while another portion of the potential stabilizing conductive film 21, which is positioned internally of the signal line 23, the second potential stabilizing conductive film 22, the die substrate 13 of the sensor die 10, and the die substrate 34 of the drive die 30 collectively function as a noise shield. The signal line 23 is completely encompassed by the aforementioned noise shields, which are very proximate to the signal line 23 with a small distance ranging from 10 μm to 100 μm therebetween, wherein the signal line 23 completely overlap with the noise shields. Thus, it is possible to improve the noise resistance with respect to the signal line 23 having a relatively high impedance.

The diaphragm 11 serving as the bias electrode is connected to the stabilized power circuit 31 via a bias line 28. Similar to the signal line 23, the bias line 28 is formed using the intermediate conductive film of the three conductive films forming the multilayered wiring substrate 20. The bias line 28 is adequately distanced from the signal line 23 so as to make a floating capacity being negligible.

In the present embodiment, the noise shield, which realizes a high noise resistance with respect to the plate 12 and the signal line 23 both having high impedance, is completely embedded inside the package of the condenser microphone. This eliminates the necessity of additionally arranging a noise shield for the condenser microphone in connection with the external wiring substrate 60 and peripheral parts. Thus, it is possible to reduce the overall cost for the noise measure adapted to the condenser microphone.

### 3. Variations

The present embodiment can be modified in a variety of ways; hence, variations will be described below.

### (a) First Variation

FIG. 5 shows a first variation of the condenser microphone, wherein the first variation differs from the embodiment shown in FIGS. 1A and 1B in that the potential stabilizing conductive film 21 is not grounded but is connected to the stabilized power circuit 31. That is, the first variation allows the potential stabilizing conductive film 21 to be electrically connected to the diaphragm 11 serving as the bias electrode, the die substrate 13 of the sensor die 10, and the stabilized power circuit 31 by way of a via. In this connection, the stabilized power circuit 31 shares both of the functions of the noise shield and bias line; hence, it is possible to simplify the constitution of the multilayered wiring substrate 20 in FIG. 5 in comparison with the constitution of the multilayered wiring substrate 20 shown in FIGS. 1A and 1B.

### (b) Second Variation

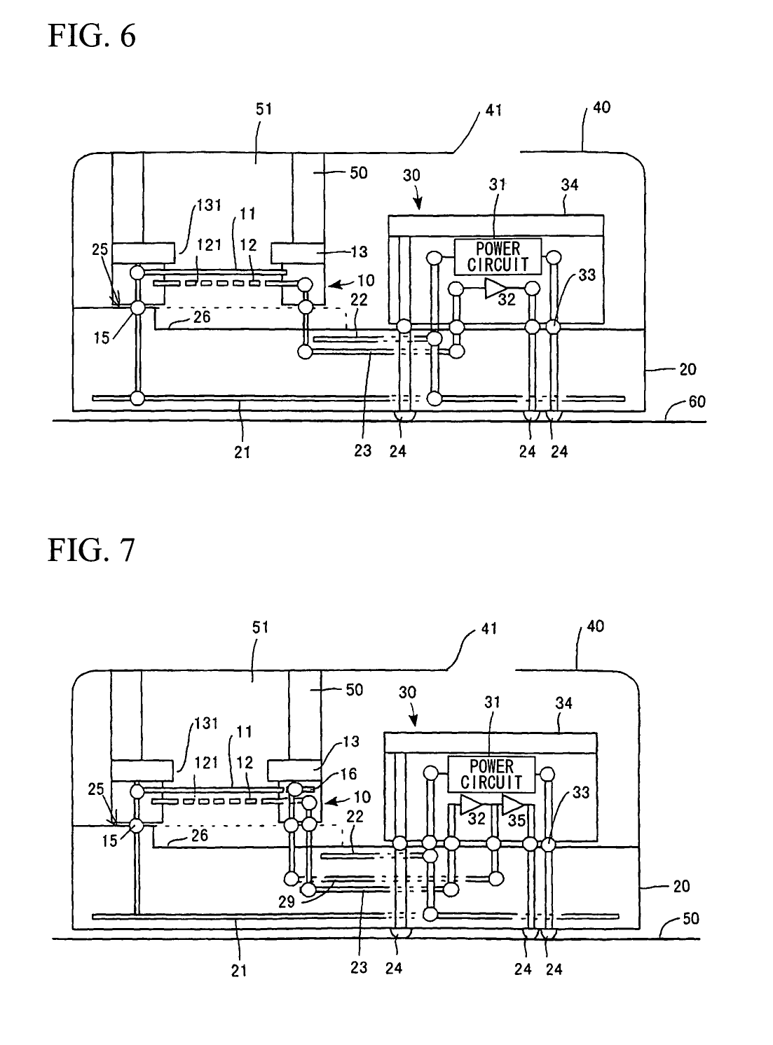

FIG. 6 shows a second variation of the condenser microphone, wherein the second variation differs from the embodiment shown in FIGS. 1A and 1B in that both the potential stabilizing conductive film 21 and the second potential stabilizing conductive film 22 are connected to the stabilized power circuit 31. That is, the second variation allows the second potential stabilizing conductive film 22 to be electrically connected to the stabilized power circuit 31 by way of a via.

### (c) Third Variation

FIG. 7 shows a third variation of the condenser microphone, wherein the third variation differs from the embodiment shown in FIGS. 1A and 1B in that a guard electrode 16 is additionally introduced so as to reduce parasite capacity formed by the conductive films forming the diaphragm 11 or to reduce parasite capacity formed by the conductive films forming the die substrate 13 and the plate 12. The guard electrode 16 is constituted of a conductive film, which is positioned between the conductive film of the plate 12 and the die substrate 13, which is positioned in the same layer as the conductive film of the diaphragm 11, and which is insulated from the conductive film of the diaphragm 11. The guard electrode 16 is connected to the output terminal of the impedance converter 32 via a guard line 29 corresponding to the intermediate conductive film of the conductive films forming the multilayered wiring substrate 20, wherein both the guard electrode 16 and the conductive film of the plate 12 (connected to the signal line 23) are set to the same potential. This eliminates parasitic capacity between the guard electrode 16 and the conductive film of the plate 12. In addition, capacity formed between the die substrate 13 and the guard electrode 16 does not substantially affect the output signal of the condenser microphone. Due to the provision of the guard electrode 16, it is possible to remarkably reduce parasitic capacity components in the output signal of the condenser microphone.

### (d) Other Variations

It is possible to further modify the condenser microphone without departing from the essential features of the present invention. For example, the electrostatic capacity sensor of the present invention can be adapted to a pressure sensor and an acceleration sensor. The package of the electrostatic capacity sensor is not necessarily limited to the MEMS package or MCP (Multi Chip Package), wherein it is possible to use wire bonding and to stack multiple dies in MCP. The electrostatic capacity sensor of the present invention can be applied to any type of electronic device such as portable telephone terminals (or cellular phones), personal digital assistants (PDA), IC recorders, and personal computers.

Lastly, the present invention is not necessarily limited to the embodiment and its variations and can be further modified in a variety of ways within the scope of the invention defined by the appended claims.

What is claimed is:

1. An electrostatic capacity sensor comprising:
a sensor die including a bias electrode and a signal electrode, which are positioned opposite to each other; and
a shield member having a joint surface joining the sensor die, wherein the shield member includes a potential stabilizing conductive film whose external shape encompasses a vertically projected area of the signal electrode in plan view,
wherein the signal electrode is positioned between the bias electrode and the potential stabilizing conductive film.

2. An electrostatic capacity sensor according to claim 1, wherein the sensor die includes
a plate having a plurality of sound holes and forming the signal electrode,
a diaphragm forming the bias electrode, which vibrates relative to the plate due to sound waves, and
a die substrate having a through-hole for exposing the diaphragm and supporting the plate and the diaphragm,
wherein the sensor die joins the joint surface of the shield member via an acoustic passage communicating with the sound holes.

3. An electrostatic capacity sensor according to claim 1 further comprising:
an impedance converter that is connected to the signal electrode so as to reduce an output impedance; and
a drive die joining the joint surface of the shield member,
wherein the shield member corresponds to a multilayered wiring substrate including
a potential stabilizing conductive film,
a second potential stabilizing conductive film whose potential is stabilized, and
a signal line that is positioned between the potential stabilizing conductive film and the second potential stabilizing conductive film and that partially overlaps the potential stabilizing conductive film and the second potential stabilizing conductive film so as to connect the signal electrode and the impedance converter together.

4. An electrostatic capacity sensor according to claim 3 further comprising a package cover that is combined with the multilayered wiring substrate so as to define an internal space for embracing the sensor die and the drive die.

5. An electrostatic capacity sensor according to claim 4 wherein the sensor die includes
a plate having a plurality of sound holes and forming the signal electrode,
a diaphragm forming the bias electrode that vibrates relative to the plate due to sound waves, and
a die substrate having a through-hole for exposing the diaphragm and supporting the plate and the diaphragm,
wherein the sensor die joins the joint surface of the shield member via an acoustic passage for communicating the sound holes with the internal space, and
wherein the package cover has an opening for communicating the internal space with an external space.

6. An electrostatic capacity sensor according to claim 5 further comprising a gasket that joins a surface of the sensor die and that has an internal cavity, which is isolated from the internal space and communicates with the through-hole of the die substrate.

7. An electrostatic capacity sensor according to claim 5, wherein the joint surface of the shield member has a recess that forms an interior wall of the acoustic passage.

8. An electrostatic capacity sensor according to claim 3, wherein the sensor die joins the multilayered wiring substrate in a flip-chip connection manner.

9. An electrostatic capacity sensor according to claim 3, wherein the multilayered wiring substrate includes a bias line for connecting both the bias electrode and the die substrate to a stabilized power circuit, and
wherein both the potential stabilizing conductive film and the second potential stabilizing conductive film are grounded.

10. An electrostatic capacity sensor according to claim 3, wherein the potential stabilizing conductive film connects both the bias electrode and the die substrate to a stabilized power circuit.

11. An electrostatic capacity sensor according to claim 10, wherein the second potential stabilizing conductive film is connected to the potential stabilizing conductive film.

12. An electronic device having an external wiring substrate on which a multilayered wiring substrate of an electrostatic capacity sensor joins,
said electrostatic capacity sensor including a sensor die including a bias electrode and a signal electrode, which are positioned opposite to each other, and
a shield member having a joint surface joining the sensor die, wherein the shield member includes a potential stabilizing conductive film whose external shape encompasses a vertically projected area of the signal electrode in plan view,
wherein the signal electrode is positioned between the bias electrode and the potential stabilizing conductive film.

13. An electronic device according to claim 12, wherein the sensor die includes
a plate having a plurality of sound holes and forming the signal electrode,
a diaphragm forming the bias electrode, which vibrates relative to the plate due to sound waves, and
a die substrate having a through-hole for exposing the diaphragm and supporting the plate and the diaphragm,
wherein the sensor die joins the joint surface of the shield member via an acoustic passage communicating with the sound holes.

14. An electronic device according to claim 12 further comprising:
an impedance converter that is connected to the signal electrode so as to reduce an output impedance; and
a drive die joining the joint surface of the shield member,
wherein the shield member corresponds to a multilayered wiring substrate including
a potential stabilizing conductive film,
a second potential stabilizing conductive film whose potential is stabilized, and
a signal line that is positioned between the potential stabilizing conductive film and the second potential stabilizing conductive film and that partially overlaps the potential stabilizing conductive film and the second potential stabilizing conductive film so as to connect the signal electrode and the impedance converter together.
